(19) United States
(12) Patent Application Publication
(10) Pub. No.: US 2014/0261612 A1
(43) Pub. Date: Sep. 18, 2014

(54) METHODS FOR MANUFACTURING THREE-DIMENSIONAL METAMATERIAL DEVICES WITH PHOTOVOLTAIC BRISTLES

(71) Applicant: Q1 NANOSYSTEMS CORPORATION, Sacramento, CA (US)

(72) Inventors: Robert SMITH, Placerville, CA (US); Mark R. Schroeder, Hollister, CA (US); Larry Bawden, El Dorado Hills, CA (US); John Fisher, Folsom, CA (US)

(73) Assignee: Q1 Nanosystems Corporation, Sacramento, CA (US)

(21) Appl. No.: 13/841,687

(22) Filed: Mar. 15, 2013

Related U.S. Application Data
(63) Continuation of application No. 13/832,095, filed on Mar. 15, 2013.

(51) Int. Cl. H01L 31/18; H01L 31/0352

(52) U.S. Cl. CPC H01L 31/18; H01L 31/035281
USPC 136/244; 438/98

(57) ABSTRACT

A metamaterial of an array of photovoltaic bristles may enable each photovoltaic bristle to have a high probability of photon absorption. The high probability of photon absorption may lead to increased efficiency and more power generation from an array of photovoltaic bristles. A completed photovoltaic device may benefit from further total efficiency gains by implementing a corrugated structure in the metamaterial and/or an assembled solar panel of metamaterials. Various methods to manufacture these metamaterial devices may include utilize stamping methods, photolithographic techniques, etching techniques, deposition techniques, as well as the creation of vias to form arrays of photovoltaic bristles for the metamaterial photovoltaic devices.

### RELATED APPLICATIONS

This application is a continuation application of U.S. patent application Ser. No. 13/830,295, entitled “Methods for Manufacturing Three-Dimensional Metamaterial Devices with Photovoltaic Bristles” filed Mar. 14, 2013, the entire contents of which are hereby incorporated by reference. This application is also related to U.S. patent application Ser. No. 13/751,914, entitled “Three-Dimensional Metamaterial Device with Photovoltaic Bristles” filed Jan. 28, 2013, the entire contents of which are hereby incorporated by reference for purposes of disclosing dimensions, materials and configurations of photovoltaic bristles that may be manufactured by the embodiment processes disclosed herein.

### FIELD

This application generally relates to photovoltaic devices, and more specifically to the methods of manufacturing photovoltaic cells featuring a large number of photovoltaic bristles.

### BACKGROUND

Solar power is a popular clean energy, but it is generally more expensive than its fossil fuel competitors (e.g., oil, coal, and natural gas) and other traditional energy sources (e.g., hydropower). Typically, solar energy is relatively expensive because traditional photovoltaic cells with a planar configuration have generally low total efficiency. Total efficiency is based upon the total power produced from a solar panel throughout the day as the sun transits across the sky. Total efficiency is different from the theoretical efficiency, which is the fraction of light energy converted to electricity by the photovoltaic cells with a zero angle of incidence (e.g., the instant when the sun is directly above the metamaterial). Thus, a high total efficiency photovoltaic cell is needed to make solar energy cost-competitive with fossil fuels and traditional energy sources.

### SUMMARY

The various embodiment methods of manufacturing and assembling may be used to produce photovoltaic cells formed from a plurality of photovoltaic bristles whose photovoltaic and conductive materials are configured to exhibit a high probability of photon absorption and internal reflection. As a result of the high probability of photon absorption and internal photon reflections, the photovoltaic cells of photovoltaic bristles exhibit high total efficiency in converting light energy into electrical energy. The high total efficiency of the embodiment photovoltaic cells may lead to increased efficiency and more power generation from the photovoltaic cell.

In various embodiments, these photovoltaic bristles may be manufactured by forming rods or cores and adding photovoltaic, conductive, and non-conductive materials over the cores. In other various embodiments, forming photovoltaic bristles may include creating vias in which photovoltaic, conductive and non-conductive materials may fill the vias to create the embodiment photovoltaic cells.

The various embodiments include creating further performance enhancements and manufacturing improvements such as creating off-angle structural features that may result in a further increase in total photon absorption by increasing the probability that photons will strike the sidewall of the photovoltaic bristles within a given angle range. Additionally, the various embodiments may further include adding current conductive traces or conductive regions to reduce electrical resistance within the embodiment photovoltaic cells when exposed to light sufficient to generate electrical potential. The increase in total photon absorption as well as the reduction in electrical resistance may further increase the efficiency and net power generated from the photovoltaic cell under certain operating conditions.

The various embodiments may include solar panels or groups of solar panels with off-angle structural features, which may create further increase photon absorption and internal reflection resulting in high total efficiency of the embodiment photovoltaic cells within the solar panel.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1A is a cross-sectional top view of an embodiment photovoltaic bristle.

FIG. 1B is a cross-sectional side view of an embodiment photovoltaic bristle.

FIG. 2A is a perspective view of an embodiment metamaterial of an array of photovoltaic bristles positioned on a flat substrate.

FIG. 2B is a cross-sectional side view of an embodiment metamaterial array of photovoltaic bristles positioned on a flat substrate.

FIG. 3A is a perspective view of an embodiment metamaterial with arrays of photovoltaic bristles positioned on a corrugated substrate.

FIG. 3B is a cross-sectional side view of an embodiment metamaterial with arrays of photovoltaic bristles positioned on a corrugated substrate.

FIG. 4A is a perspective view of an embodiment metamaterial with arrays of photovoltaic bristles positioned on alternating slanted substrate surfaces of a corrugated substrate.

FIG. 4B is a cross-sectional side view of an embodiment metamaterial with arrays of photovoltaic bristles positioned on alternating slanted substrate surfaces of a corrugated substrate.

FIG. 5 is an illustration of embodiments shown in FIGS. 2A, 3A, and 4A positioned on the slanted planes of a structure facing away or towards the equator.

FIGS. 6A-6H are cross-sectional side views illustrating an embodiment method for forming an array of photovoltaic bristles for a metamaterial device stamping process.

FIGS. 6I-6K are cross-sectional side views illustrating an embodiment method for forming an array of photovoltaic bristles using a molding process.

FIGS. 7A, 7B, and 7C are side views of a molding process embodiment for forming a substrate and form arrays of cores on the shaped substrate.

FIG. 8 is a process flow diagram illustrating the embodiment methods illustrated in FIGS. 6A-6K and 7A-7C.

FIGS. 9A-9J are cross-sectional side views illustrating an embodiment method a plating process to form an array of bristles for a metamaterial device.

FIG. 10 illustrates an embodiment plating method for forming the embodiment metamaterials.

FIGS. 11A-11L are cross-sectional side views illustrating an embodiment method for forming the embodiment metamaterial by creating vias using photolithographic and etching techniques and subsequently removing the original substrate.

FIG. 12 is a process flow diagram illustrating the embodiment method for forming the embodiment metamaterials illustrated in FIGS. 11A-11L.

FIGS. 13A-13L are cross-sectional side views illustrating an embodiment method for forming the embodiment metamaterial by creating vias using photolithographic and etching techniques while leaving the etched substrate intact.

FIGS. 13M-13O are cross-sectional side views illustrating an alternative embodiment method for creating vias using lasers.

FIG. 14 is a process flow diagram of the embodiment method illustrated in FIGS. 13A-13L.

FIGS. 15A-15J are cross-sectional side views illustrating an embodiment method for forming the embodiment metamaterial by creating vias using a stamping method and leaving the substrate intact.

FIGS. 15K-15M are cross-sectional side views for forming the embodiment metamaterial by molding a substrate and leaving the substrate intact.

FIG. 16 is a process diagram of the embodiment method for forming the metamaterial illustrated in FIGS. 15A-15J.

FIG. 17 is a cross-sectional side view of an array of photovoltaic bristles positioned on a flat substrate with current conducting traces on top of short photovoltaic bristles.

FIG. 18 is a top view of the metamaterial of FIG. 17.

FIG. 19 is a cross-sectional side view of an array of photovoltaic bristles positioned on a flat substrate with current conducting traces between photovoltaic bristles.

FIG. 20 is a top view of metamaterial of FIG. 19.

FIG. 21 is a cross-sectional side view of an array of photovoltaic bristles positioned on a corrugated substrate with current conducting traces between photovoltaic bristles.

FIGS. 22A-22H are cross-sectional side views illustrating methods for adding current conducting traces to the outer conductive layer of a metamaterial.

FIG. 23 is a process flow diagram of the embodiment method for depositing current conducting traces on the outer conductive layer of a metamaterial illustrated in FIGS. 22A-22F.

FIGS. 24A-24J are cross-sectional side views illustrating methods for adding current conducting traces to an inner conductive layer of a metamaterial.

FIGS. 24K-24M are cross-sectional side views of methods using a laser prior to adding current conducting traces to an inner conductive layer of a metamaterial.

FIG. 25 is a process flow diagram of the embodiment method for depositing current conducting traces on an inner conductive layer of a metamaterial illustrated in FIGS. 24A-24J.

FIG. 26 is a perspective view of embodiment metamaterials in a solar panel section including a corrugated base.

FIG. 27 is a top view of a section of a solar panel with a corrugated base According to an embodiment.

FIG. 28 is a side view of a section of a solar panel with a corrugated base according to an embodiment.

FIG. 29 is an exploded view of a section of a solar panel with a corrugated base according to an embodiment.

FIG. 30 is a back view of a section of a solar panel with a corrugated base according to an embodiment.

FIG. 31 is a perspective view of a solar panel according to an embodiment.

FIG. 32 is an exploded view of a solar panel according to an embodiment.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims. Any reference to claim elements in the singular, for example, using the articles “a,” “an,” or “the” is not to be construed as limiting the element to the singular. The terms “example,” “exemplary,” or any term of the like are used herein to mean serving as an example, instance, or illustration. References to particular examples and implementations are for illustrative purposes, and are not intended to limit the scope of the invention or the claims. Any implementation described herein as an “example” is not necessarily to be construed as preferred or advantageous over another implementation.

As used herein, the term “photovoltaic bristle” refers to a three-dimensional structure approximately cylindrical with a height approximately equal to 1-100 microns, a diameter of approximately 0.2-50 microns that includes at least one photovoltaically-active semiconductor layer sandwiched between a conductive inner layer or core and a transparent outer conductive layer (e.g., TCO and a nonconductive outerlayer). The term “bristle” is used merely because the structures have a length greater than their diameter, the structures have a generally (on average) circular cross-section, and the overall dimensions of the structures are on the dimensions of sub-microns to tens of microns. In the embodiment illustrated herein the photovoltaic bristles have an approximately cylindrical shape, by which it is meant that a substantial portion of the exterior surface of the structures have a cross-section that is approximately circular or elliptical with both radii being approximately coexistent. Due to manufacturing variability, no single photovoltaic bristle may be exactly cylindrical in profile, but when considered over a large number of photovoltaic bristles the average profile is approximately cylindrical. In another embodiment, the photovoltaic bristles may have a non-circular cross-section, such as hexagonal, octagonal, elliptical, etc. as may facilitate manufacturing.

When the embodiment photovoltaic bristles are arranged on a substrate in an order or disordered array, the resulting structure may form a metamaterial structure. As used herein, the term “metamaterial” or “metamaterial substrate” refers to an array of photovoltaic bristles on a substrate. Metamaterials as used herein are artificial materials that are engineered with metals or polymers that are arranged in a particular structured or non-structured pattern that result in material properties (including light absorption and refraction properties) that are different from the component materials. The cumulative effect of light interacting with the array of photovoltaic bristles may be affected by controlling the shape, geometry, size, orientation, material properties, material thicknesses, and arrangement of the bristles making up the metamaterial as described herein.

Traditional planar photovoltaic cells are flat. In traditional planar photovoltaic cells, a limited number of photons are absorbed at any given point in time. Photon absorption occurs through the thickness of the traditional planar photovoltaic cell (e.g., top-to-bottom) from the point of photon entry until the photon is converted to electrical energy. Traditional planar photovoltaic cells convert photons into electrical energy when photons interact with a photovoltaic layer. However, some photons pass through the photovoltaic layer without generating electron-hole pairs, and thus represent lost energy. While the number of photons absorbed may be increased by making the photovoltaic layer thicker, increasing the thickness increases the fraction of electron-hole pairs that recombine, converting their electrical potential into heat. Additionally, thicker photovoltaic films exhibit an exponential attenuation loss leading to a decrease in photon conversion. For this reason, traditional planar photovoltaic cells have emphasized thin photovoltaic layers, accepting the reduced photon-absorption rate in favor of increased conversion of electron-hole pairs into electrical current and reduced heating. The theoretical peak efficiency, as well as the total efficiency, of traditional planar photovoltaic cells is thus limited by the planar geometry and the un-attenuated fraction of photons that can be absorbed in a maximized optical path length through the photovoltaic layer.

Conventional planar photovoltaic cells also suffer from low total efficiency in static deployments (i.e., without sun tracking equipment), since their instantaneous power conversion efficiency decreases significantly when the sun is not directly overhead (i.e., before and after noon). Peak efficiencies of traditional planar photovoltaic cells are affected by their orientation with respect to the sun, which may change depending on the time of day and the season. The standard test conditions for calculating peak efficiencies of solar cells are based on optimum conditions, such as testing the photovoltaic cells at solar noon or with a light source directly above the cells. If light strikes traditional photovoltaic cells at an acute angle to the surface (i.e., other than perpendicular to the surface) the instantaneous power conversion efficiency is much less than the peak efficiency. Traditional planar photovoltaic cells in the northern hemisphere are typically tilted toward the south by an angle based on the latitude in order to improve their efficiency. While such fixed angles may account for the angle of the sun at noon due to latitude, the photovoltaic cells receive sunlight at an angle during the morning and afternoon (i.e., most of the day). Thus, traditional planar photovoltaic cells actually result in a low total efficiency and low total power generation when measured beyond a single moment in time.

The various embodiments include photovoltaic cells that exhibit metamaterial characteristics from regular or irregular arrays of photovoltaic bristles configured so the conversion of light into electricity occurs within layers of the photovoltaic bristles. Since the photovoltaic bristles extend above the surface of the substrate and are spaced apart, the arrays provide the photovoltaic cells of the various embodiments with volumetric photon absorption properties that lead to energy conversion performance that exceeds the levels achievable with traditional planar photovoltaic cells. The volumetric photon absorption properties enable the various embodiment photovoltaic cells to generate more power than traditional planar photovoltaic cells with the same footprint. Due to the small size of the photovoltaic bristles, the photovoltaically-active layers within each bristle are relatively thin, minimizing power losses due to electron-hole recombination. The thin photovoltaically-active layers help reduce attenuation losses normally present in thicker photovoltaic films because the photovoltaic bristles include a thin radial absorption depth and a relatively thicker vertical absorption depth maximizing photon absorption and power generation through the combined long circumferential absorption path length and short radial electron path length. When individual photovoltaic bristles are combined in an array on, or within, a substrate, a metamaterial structure may be formed that exhibits a high probability of photon absorption and internal reflection that leads to increased energy conversion efficiencies and power generation. Various embodiment structures also provide additional performance-enhancing benefits as will be described in more detail below.

Further performance enhancements may be obtained by positioning the embodiment photovoltaic cells so that the photovoltaic bristles' sidewalls are at an angle to the incident photons. This can improve the probability that photons will be absorbed into the photovoltaic bristles due to wave interactions between photons and the outer conductive layer on each photovoltaic bristle. Orienting the embodiment photovoltaic bristles at an angle to the incident photons also increases the circumferential optical depth of the photovoltaic bristles exposed to the light, since in such an orientation the photons strike the sides of the bristles and not just the tops. The off-axis photon absorbing characteristics of the photovoltaic bristles also enables the embodiment photovoltaic cells to exhibit significant total energy conversion efficiency for indirect and scattered light, thereby increasing the number of photons available for absorption compared to a conventional photovoltaic cell.

An embodiment described herein includes photovoltaic cells featuring arrays of photovoltaic bristles on roughly corrugated surfaces in order to present the bristles at an angle to incident sunlight. Further embodiments described herein include methods for manufacturing photovoltaic cells featuring arrays of photovoltaic bristles, as well as assembly of such photovoltaic cells into solar panels.

For purposes of background on the physics and geometries that enable photovoltaic bristles to achieve significant improvements in peak power performance, an overview of embodiment photovoltaic bristles and corresponding photovoltaic cells is now presented. More details on the dimensions, materials and configurations of embodiment photovoltaic bristles are disclosed in U.S. patent application Ser. No. 13/751,914 that is incorporated by reference above.

FIG. 1A illustrates a cross-sectional top view of one photovoltaic bristle 101 and FIG. 1B illustrates a cross-sectional side view of the photovoltaic bristle 101 of FIG. 1A. FIGS. 1A and 1B illustrate the path traveled by a photon entering the side of the outer periphery of the photovoltaic bristle 101. A photovoltaic bristle 101 may guide an absorbed photon 112 so that it follows an internal path 113 that exhibits a high probability that the photon remains within the photovoltaic bristle 101 due to total internal reflection. A photovoltaic bristle may exhibit total internal reflection by controlling the thickness of the layers 103 and 111 and by radially ordering the materials by indexes of refractions from a low index of refraction on the outside to a higher index of reaction in each inner layer, the photovoltaic bristle 101 may refract or guide photons 112 toward the core of the photovoltaic bristle 101. Since the core 106 may be highly conductive, it is also highly reflective, so that it will reflect photons 112. As illustrated, due to the large difference in index of refraction between the absorber layer and the outer conductive layer 103, photons striking this boundary at an angle will be refracted inward. As a result of these reflections and refractions, photons 112 may be effectively trapped within the absorption layer 111 for a longer period of time, thereby increasing the probability of interaction with the absorption layer 11 causing an electron-hole pair to be formed. Increasing the probability of photon absorption may result in more electrical current being generated for the same amount of incident light energy by the embodiment photovoltaic cells than is achievable by conventional photovoltaic cells.

It should be noted that the embodiment shown in FIGS. 2A-2B may include an inner reflector due to a metal core 106. In other embodiments, a refraction layer may be applied over the core 106 to achieve the same photon reflection effects. In such an embodiment, a reflective layer may be formed over the conductive core and under the absorber layer, such as a semiconductor or dielectric material layer having a lower index of refraction than the absorber layer. This refraction layer may be configured to reflect the photon at the interface between the reflection layer and the absorber layer, and not rely on reflection off of the conductive core 106. For example, such a diffraction layer may be formed from an aluminum doped zinc oxide layer of about 500-1500 angstroms in thickness. Reflected photons then refract through each layer 104, 105 until they reach the outer conductive layer 103, where the difference in the index of refraction between the absorption sublayer 105 and the outer conductive layer 103 causes the photons to reflect back into the absorption layers of the photovoltaic bristle. The reflected photons that are not reflected inwardly at the boundary between the outer conductive layer 103 and the absorption sublayer 105 may pass through the outer conductive layer 103 and be reflected off of the interface between the outer conductive layer 103 and air due to the difference in the index of refraction at this interface. In either manner, photons may remain within the photovoltaic bristle passing back and forth through the absorption layer 111 until they are eventually absorbed or exit the bristle.

Each photovoltaic bristle 101 is made up of a core 106 that may be conductive or has a conductive outer surface, an absorption layer 111 and an outer conductive layer 103, which will typically be a transparent conductive layer such as a transparent conductive oxide or transparent conductive nitride. Due to the cylindrical form of photovoltaic bristles, the absorption layer 111 surrounds the core 106, and the outer conductive layer 103 surrounds the absorption layer 111. Although, two absorber sublayers 104, 105 are shown, it should be noted that the absorption layer 111 may include any number of absorber sublayers or regions of photovoltaically-active materials or combinations of photovoltaic materials. For example, the absorption layer 111 may include multiple absorber sublayers or regions that form a p-n junction, a p-i-n junction, or multi-junction regions, which have a generally circular cross-section as illustrated in FIG. 1A. If the absorption layer 111 forms a p-i-n junction with three absorber sublayers, one sublayer may be the intrinsic portion forming the p-i-n junction. If the core 106 is a semiconductor core forming a p-n junction with a single absorber sublayer, the absorption layer 111 may include only one sublayer. Regardless of the number, the absorber sublayers or regions 104, 105 may be made from one or more of silicon, amorphous silicon, polycrystalline silicon, single crystal silicon, cadmium telluride, gallium arsenide, aluminum gallium arsenide, cadmium sulfide, copper indium selenide, and copper indium gallium selenide.

The relative radial positions of the p-type, intrinsic, or n-type sublayers/regions may vary in different embodiments. For example, in one embodiment the p-type semiconductor material may be positioned radially inside the n-type semiconductor material. In another embodiment, the n-type semiconductor material may be positioned radially inside the p-type semiconductor material. In addition, multiple materials may be used to create a sequence of p-n and/or n-p junctions, or p-i-n junctions in the absorption layer. For example, the absorption layer may include an absorber sublayer of p-type cadmium telluride (CdTe) and an absorber sublayer of n-type cadmium sulfide (CdS). In an embodiment, the absorption layer 111 may be fully depleted. For example, the p-type region and the n-type region forming the sublayer or region 104 and the sublayer or region 105 may be fully depleted.

In an example embodiment, the absorption layer 111 may include a p-type semiconductor sublayer 105, such as p-type cadmium telluride, and an n-type semiconductor sublayer of a different material, such as n-type-cadmium sulfide. In another example embodiment, one sublayer 104 may be a p-type region, such as p-type amorphous silicon, and another sublayer 105 may be an n-type region of the same material as the sublayer 104 but doped to form an n-type semiconductor, such as n-type amorphous silicon.

The outer conductive layer 103 has a radial thickness which may be measured radially from the outer surface of the absorption layer 111 to the outer surface of the outer conductive layer 103 (i.e., the outer surface of the photovoltaic bristle). In an embodiment, the outer conductive layer 103 is a transparent conductive oxide (“TCO”), such as a metal oxide. In an embodiment, the outer conductive layer 103 may include a dopant creating a p-type or n-type transparent conductive oxide. For example, the transparent conductive oxide layer 103 may be one of intrinsic zinc oxide, indium tin oxide, and cadmium tin oxide (Cd₂SnO₄). In an embodiment, the outer conductive layer 103 may include a transparent conductive nitride such as titanium nitride (TiN). In another embodiment, the outer conductive layer 103 may include a buffer with or without the dopant. Some examples of an outer conductive layer 103, which may be a transparent conductive oxide with a dopant, include boron-doped zinc oxide, fluorine doped zinc oxide, gallium doped zinc oxide, and aluminum doped zinc oxide. Some examples of buffers that may be added to a transparent conductive oxide include zinc stannate (Zn₂SnO₄), titanium dioxide (TiO₂), and similar materials well known in the art.

Although not shown in FIGS. 1A-1B, the outer conductive layer 103 may include any number of conductive and/or non-conductive sublayers to achieve a particular total optical thickness while simultaneously having a thin conductive sublayer. With multiple sublayers, the outer conductive layer 103 may also benefit from adding flexibility to the photovoltaic bristles for a more resilient photovoltaic bristle metamaterial device. The addition of a non-conductive sublayer may have refractive properties that improve off-angle photon absorption efficiency. Analysis and observations of prototypes indicate that outer conductive layers between 500 and 15,000 angstroms result in a decrease in electrical resistance in the conductive layers from field effects at the structural discontinuities in the photovoltaic bristles. However, the outer conductive layer 103 may need to be of a minimum optical thickness exceeding 500 and 15,000 angstroms a bristle to achieve the photon trapping and guiding effect shown in FIG. 1A. Thus, the outer conductive layer 103 may include multiple layers to achieve the conflicting optical thickness requirement and the requirement for electrical resistivity benefits from field effects. As an example, the outer conductive layer 103 may have two sublayers including a conductive sublayer such TCO and a non-conductive sublayer such as an optically transparent polymer. As another example, the non-conductive sublayer may be a bi-layer including TCO and a polymer or glass. As a further example, the outer conductive layer 103 may include three sublayers where a non-conductive sublayer separates two conductive sublayers.

In an embodiment, the core 106 may be of a variety of conductive materials and non-conductive materials. In an embodiment, the core 106 may be a solid conductive core such as a metal. For example, the solid conductive core may be gold, copper, nickel, molybdenum, iron, aluminum, or silver. In an embodiment, the core 106 may include the same material as the substrate 202 (shown in FIG. 2B). For example, the core 106 and the substrate 202 may include a polymer. In another embodiment, the core 106 may include a different material than the substrate 202. In another embodiment, an inner conductive layer 107 may surround the core 106. For example, the inner conductive layer 107 may be gold, copper, nickel, molybdenum, iron, aluminum, or silver to create a conductive core. In an embodiment, the core 106 may include a polymer with an inner conductive layer 107 surrounding the polymer. The inner conductive layer 107 may include similar material as the outer conductive layer 103. For example, the inner conductive layer 107 may include a transparent conductive oxide, a transparent conductive nitride, and/or a non-conductive transparent material. The inner conductive layer 107 may include multiple layers (e.g., sublayers of TCO and a non-conductive optically transparent polymer) to achieve the conflicting benefits of field effects and proper optical depth for the photovoltaic device. In an embodiment, the core 106 may include a semiconductor material. For example, the core 106 may be made from one or more of silicon, amorphous silicon, polycrystalline silicon, single crystal silicon, cadmium telluride, gallium arsenide, aluminum gallium arsenide, cadmium sulfide, copper indium selenide, and copper indium gallium selenide.

FIG. 1B also illustrates that photons striking the photovoltaic bristle 101 will have a higher probability of absorption when they strike the sidewall of a photovoltaic bristle at a compound angle that is less than 90 degrees but more the 0 degrees to the surface, where an angle perpendicular to the sidewall surface is considered to be 0 degrees. The compound incident angle includes a vertical plane component 133 (shown in FIG. 1B) and a horizontal plane component 132 (shown in FIG. 1A). The horizontal plane component 132 is defined by a photon 112 striking the outer surface of the bristle at a point along the perimeter of the circular cross-section plane forming an angle with the perimeter where an angle perpendicular to the perimeter is considered 0 degrees. Similarly, the vertical plane component 133 is defined by the photon 112 striking the outer surface of the bristle at a point along the height forming a vertical angle with the surface where an angle perpendicular to the surface is considered 0 degrees.

Analysis of photon absorption characteristics of the outer conductive layer have revealed that photons striking the surface of the sidewall of the photovoltaic bristle perpendicular to the horizontal component 132 and the vertical component 133 may result in a compound angle of 0 degrees and an increased probability of being reflected off the surface. Similarly, photons striking the surface of the sidewall of the photovoltaic bristle parallel to the vertical and the horizontal component will also have an increased probability of being reflected off the surface. However, photons striking the side surface at a compound angle between 10° and 80° have a high probability of being absorbed into the outer conductive layer 203. Once absorbed, the internal refraction characteristics of the absorber sublayers 104, 105 and outer conductive layer 103 cause the photons to remain within the photovoltaic bristle 101 for an extended time or path length. This characteristic is very different from conventional photovoltaic cells, which exhibit the maximum power conversion efficiency when the angle of incidence of photons is normal to its single planar surface.

The difference between the incident angle corresponding to conventional photovoltaic cells and the photovoltaic bristles is illustrated by angle θₚ in FIG. 1B. The preferred incident angle for a traditional solar cell, θₚ, would form a right angle with the top of the bristle as well as the substrate of the full metamaterial device (not shown). Thus, not only does the photovoltaic bristle exhibit better absorption characteristics at off-angles (not perpendicular or parallel to the surface), the reference point for measuring an off-angle is different from that of a conventional photovoltaic cells. For a metamaterial device with photovoltaic bristles, the reference point is measured from the sidewall of a bristle in two planes, which is unachievable by a planar photovoltaic cell. Thus, due to the off-angle absorption characteristics of photovoltaic bristles, the embodiment photovoltaic cells exhibit significant power conversion efficiency across a broad range of angle of incidence. This translates to more power generation throughout the day than achievable from fixed solar panels with conventional planar solar arrays that produce their peak efficiencies (i.e., maximum power generation) when the sun is directly overhead.

FIG. 2A illustrates a perspective view of metamaterial 200 comprising an array of photovoltaic bristles 201a, 201b, 201c, 201d, 201e, 201f, 201g, 201h, 201i, 201j, 201k, 201l, 201m, 201n, 201o, 201p extending from a flat substrate 202 (shown in FIG. 2B). While illustrated with twelve photovoltaic bristles 201a-201p, a metamaterial may include a larger number of photovoltaic bristles. The number of photovoltaic bristles 201 will depend upon the dimensions and spacing of the bristles and the size of the photovoltaic cell. As with conventional photovoltaic cells, metamaterials may be assembled together in large numbers to form panels (i.e., solar panels) of a size that are suitable for a variety of installations.

Each photovoltaic bristle 201a-201p is characterized by its height “h,” which is the distance that each bristle extends from the substrate 202. Photovoltaic bristles 201a-201p are also characterized by their radius “r”. In an embodiment, all photovoltaic bristles 201a-201p within an array will have approximately the same height h and approximately the same radius r in order to facilitate manufacturing. However, in other embodiments, photovoltaic bristles 201a-201p within the array may be manufactured with different heights and diameters.

In an embodiment, the number of photovoltaic bristles in a photovoltaic cell may depend upon the substrate surface area available within the cell and the packing density or inter-bristle spacing. In an embodiment, photovoltaic bristles may be positioned on the substrate with a packing density or inter-bristle spacing that is determined based upon the bristle dimensions (i.e., h and r dimensions) as well as other parameters, and/or pattern variations. For example, a hexagonal pattern may be used rather than the trigonometric pattern shown in FIG. 2A.

In the various embodiments, the dimensions and the inter-bristle spacing of photovoltaic bristles may be balanced against the shading of neighboring bristles. In other words, increasing the number of photovoltaic bristles on a plane may increase the surface area available for absorbing photons. However, each photovoltaic bristle casts a small shadow, so increasing the photovoltaic bristle density of a photovoltaic cell beyond a certain point may result in a significant portion of each bristle being shadowed by its neighbors. While such shadowing may not reduce the number of photons that are absorbed within the array, shadowing may decrease the number of photons that are absorbed by each photovoltaic bristle, and thus there may be a plateau in the photon absorption versus packing density of photovoltaic bristles.

A further consideration beyond shadowing is the wave interaction effects of the array of closely packed photovoltaic bristles. The interior-bristle spacing may be adjusted to increase the probability that photons entering the array are absorbed by the photovoltaic bristles' metamaterial properties considering the bulk material properties of the layered films that makeup the array. For example, specific characteristics such as extinction coefficient or absorption path length may predict an optimal dimensional design, although one may chose to deviate from this prediction resulting in a sacrifice in performance.

FIG. 2B is a cross-sectional side view of a section of metamaterial 200 including photovoltaic bristles 201m, 201n, 201o, and 201p as illustrated in FIG. 2A. As shown in FIG. 2B the photovoltaic bristles extend from a substrate 202. In an embodiment, the core 106 may be the same material as the substrate 202 and an inner conductive layer 107 may surround the core 106. The absorber layer 111 may surround the inner conductive layer 107 and the outer conductive layer 103 may surround the absorber layer 111. The absorber layer 111 may include any number of sublayer or regions. As illustrated in FIG. 2B, the absorber layer 111 may include two sublayers or regions 104, 105. In an embodiment, the two absorber sublayers or regions 104, 105 may be any semiconductor material where one sublayer or region is doped as n-type and the other is doped as p-type.

The metamaterial 200 may include a substrate 202 of any suitable substrate material known to one skilled in the art. For example, the substrate 202 may be glass, doped semiconductor, diamond, metal, a polymer, ceramics, or a variety of composite materials. The substrate 202 material may be used elsewhere in the metamaterial 200, such as a material used in any layer of a photovoltaic bristle 201m-201n. Alternatively, the material used in the substrate 202 may be different from other materials used in the photovoltaic bristles 201m-201n. In an embodiment, the core 106 and the substrate 202 may include a common material. For example, the substrate 202 and the core 106 may include glass, semiconductor material, a polymer, ceramics, or composites. In a further embodiment, the core 106 and substrate 202 may include similar materials, while the inner conductive layer 107 is added over the substrate 202 and surrounding the core 106 creating a conductive core. The inner conductive layer 107 may include metal such as gold, copper, nickel, molybdenum, iron, aluminum, or silver. Alternatively, the inner conductive layer may include any of the materials used for the outer conductive layer 103 which may be used in combination with the previously listed metals.

In an embodiment, the inner conductive layer 107 may also be an inner refraction or reflection layer that is added on top of the core 106 in order to provide an inner reflection interface for photons. In this embodiment, a layer of semi-conductive or insulator material, such as B:ZnO, Al:ZnO, ZnO, or ITO, may be applied over the metal core. This layer may be at least one-half wavelength in thickness, depending on the refractive index of the material. For example, such a layer made of Al:ZnO (AZO) may be approximately 500 to 1500 angstroms thick over which the absorber layer may be applied. Such an AZO layer has a refractive index that is lower than the absorber layer. This difference in refractive index coupled with the curvature of the interface of these two layers will reflect the photons before they reach the metal core. The reflection induced by this design may exhibit lower losses than the designs in which photons reflect from a metal surface of the core. The use of such a refraction layer may be included in any of the embodiments illustrated and described herein. For example, in the embodiments in which the center of the core is a plastic rod, a metal layer is applied over the plastic core and then the AZO is applied over the metal layer. In further embodiments, this refractive layer forming a reflecting interface may be formed using multiple layers, such as: ITO-AZO; ITO-AZO-ITO; TiO2-TiN—TiO2; ZnO-AZO-ZnO; etc. Such multiple layers may function similar to a Bragg reflector used in fiber optics.

In ordering reason the percentage of solar photons striking photovoltaic bristles at the appropriate angle of incidence, one embodiment orients the photovoltaic bristles at an angle on a corrugated substrate. Positioning photovoltaic bristles at an angle to incident light increases the probability of off-axis photon absorption, which may reflect and propagate photons around and within the photovoltaic bristles, thereby developing an equilibrium standing wave and increasing probability of converting photon energy into electrical energy. Consequently, embodiment photovoltaic cells with such a corrugated shape may generate more electrical power than is possible from conventional photovoltaic cells.

In addition to increasing the probability of photon absorption, embodiment corrugated photovoltaic cells provide more surfaces and more photovoltaic bristles for photon absorption within a given planar footprint than a comparable flat substrate configuration. Each corrugated photovoltaic cell may include a large number of angled surfaces with photovoltaic bristles, compared to a conventional flat substrate photovoltaic cell that has only a single flat surface or absorbing photons. The improvements from the corrugated photovoltaic cell results in an increase in optical volume enabling more photon absorption and power generation from such a metamaterial device.

FIG. 3A is a perspective view of an embodiment metamaterial 300 comprising a corrugated shaped substrate 302 (shown in FIG. 3B) with arrays of photovoltaic bristles 301 positioned on each slanted substrate surface 308a, 308b, 308c, 309a, 309b, and 309c. Although FIG. 3A depicts six slanted substrate surfaces, in an embodiment, the metamaterial 300 may have a larger number of slanted substrate surfaces. In FIG. 3A, each slanted substrate surface 308a-308c, and 309a-309c may form an angle θ_{b} with the flat foundation 303 of the substrate 302. In an embodiment angle θ_{b} may be between about 30 and about 60 degrees. In further embodiments the angle θ_{b} may be 30-35 degrees, 35-40 degrees, 40-45 degrees, 45-50 degrees, 50-55 degrees, and 55-60 degrees. In an embodiment, arrays of photovoltaic bristles 301 may be oriented so that their long axis is normal to the slanted substrate surfaces 308a-308c and 309a-309c including angle θ_{b} to increase the probability of photon absorption and photon trapping and guiding from photons striking the sidewalls of each photovoltaic bristles 301 at compound angles approximately between 10 and 80. It should be noted that each slanted substrate surface 308a-308c and 309a-309c may include any number of photovoltaic bristles 301 (i.e. more than the twelve photovoltaic bristles 301 shown in the figure).

FIG. 3B is a cross-sectional side view of a section of a metamaterial 300 comprising slanted substrate surfaces 308a and 309a at angles θ_{b} with the foundation 303 and an array of photovoltaic bristles 301 on each slanted substrate surface. As described above, each photovoltaic bristle 301 may include a core 106, an inner conductive layer 107, and an absorber layer 111 with absorber sublayers 104, 105 surrounding the inner conductive layer, and an outer conductive layer 103 surrounding the absorber layer 111. In an embodiment, the core 106 may be the same material as the substrate 302. The photovoltaic bristles 301 extend from the corrugated surface 302 perpendicular to each slanted surface 308, 309. As illustrated in the figure, this angle enables photons 112 traveling along the photon path 113 to enter the sidewall of the photovoltaic bristle 301 at a compound angle of approximately 10-80°.

In another embodiment, photovoltaic bristles are position only on alternating slanted surfaces of the corrugated substrate, with the opposite surfaces lacking such structures. This embodiment configuration may reduce manufacturing costs while presenting photovoltaic bristles on the services most likely to receive solar radiation when deployed. Additionally, the slanted surfaces that do not include photovoltaic bristles may be coated with a reflective material (e.g., a metal) so that photons striking that surface are reflected at a desirable angle into the photovoltaic bristles on the opposite surface. Such an embodiment is illustrated in FIGS. 4A and 4B.

FIG. 4A is a perspective view of metamaterial 400 comprising a corrugated shaped substrate 402 (shown in FIG. 4B) and arrays of photovoltaic bristles 401 positioned at normal from the planes of alternating slanted substrate surfaces 408a, 408b, and 408c. In an embodiment, slanted substrate surfaces 409a, 409b, and 409c may be without arrays of photovoltaic bristles 401 and may be configured with a reflective surface coating, such as a metal, that may reflect photons into the photovoltaic bristles on the opposite surface is illustrated in FIG. 4B. Although FIG. 4A depicts six slanted substrate surfaces, in an embodiment, the metamaterial 400 may have a larger or smaller number of slanted substrate surfaces.

FIG. 4B is a cross-sectional side view of a section of metamaterial 400 with a corrugated substrate 402 comprising slanted substrate surfaces 408a, 408b, 409a, 409b at angles θ_{b} with the foundation 403. In an embodiment, each slanted substrate surface 408a, 408b may include an array of photovoltaic bristles 401 configured approximately normal to the slanted substrate surface. In an embodiment, slanted substrate surfaces 409a and 409b may include a reflective layer 405. As such, the reflective layer 405 may reflect photons 411 along a photon path 412 so that the reflected photons 411′ strikes the photovoltaic bristles extending from the adjacent slanted substrate surface 408b of the substrate 402. In embodiment, a reflective layer 405 (i.e., reflective film) may be any material that has high reflective characteristics to reflect photons usable for the embodied metamaterial.

FIG. 5 illustrates an advantage of the various embodiment photovoltaic cells when installed on a typical structure 502 (e.g., a house) having a roof with angled surfaces 504, 506. In this illustrative figuration, photovoltaic cells 200 on a northern facing roof surface may have a flat profile and feature photovoltaic bristles 201 that extend perpendicular from the surface. Since this surface of the roof 506 receives sunlight at an angle, the incident sunlight on this surface is preferable for increasing photon absorption on such a photovoltaic cell 200. On the southern facing roof surface 504, corrugated photovoltaic cells 300, 400 may be used since the sunlight will be striking the roof surface 504 at closer to a perpendicular angle of incidence. The 301, 304 angular orientation of the photovoltaic bristles on such corrugated photovoltaic cells 300, 400 ensures that incident sunlight strikes the photovoltaic bristles at angles of incidence that will increase photon absorption.

Various embodiments methods of making photovoltaic bristles are now presented.

An embodiment method 800 for manufacturing photovoltaic bristles using a press or stamping process is illustrated in FIGS. 6A-6H, 7A-7C, FIG. 8. This embodiments method 800 may enable fabricating photovoltaic bristles using low-cost substrate materials such as plastics and polymers that may be processed rapidly in large volumes. This embodiment method will be described with reference to FIGS. 6A-6H and FIG. 8 together.

In method 800 in block 804, a plastic or polymer block or starting material may be processed in order to prepare it for a pressing or forming operation. The methods used for preparing such a polymer for pressing will depend upon the type of plastic or polymer selected. As illustrated in FIGS. 6A and 6B, in block 808 A die or mold 602 including a number of solicitors will hold 604 for forming the bristle cores may be pressed into the plastic or polymer material 202 and then removed, thereby forming an array of cores 106 out of the plastic polymer 202. In an embodiment, vertical stamp 602 moves in a downward vertical manner into a polymer substrate 202 forming cores 106 and moving vertically away from the substrate 202 and the formed cores 106. Alternatively, a rolling press or rolling die may be applied to a moving sheet or tray of material similar to printing press techniques.

In block 810, the newly formed array of cores 106 may be cured or otherwise processed in order to improve the material properties, such as to harden the material. This may involve processing with heat, ultraviolet radiation, and/or chemical vapor exposure, as would be well-known in the polymer arts and depend upon the type of material used. In an embodiment, the material processing in block 810 may be accomplished as part of the stamping operation in block 808, partly as part of the stamping operation and as a host stamping process, or entirely as a post-stamping process. For example, a rolling stamp may include an ultraviolet light that is configured so that when the rolling stamp rotates over the unformed substrate 202 the ultraviolet light simultaneously cures or partially cures the newly formed cores 106.

As illustrated in FIG. 6C, in block 812, and inner conductive layer 107 may be formed over the cores 106. This may be accomplished by chemical vapor deposition, plasma enhanced chemical vapor deposition, physical deposition, plasma deposition, sputtering techniques, or electro-deposition techniques. The inner conductive layer 107 may further be formed or thickened by electroplating processes. Multiple conductive layers may be applied as part of block 812. In an embodiment, the inner conductive layer or layers may be one or more of copper, aluminum, gold, nickel, titanium, silver, tin, tantalum, and chromium, as well as alloys of such metals. This process forms an inner conducting core for the photovoltaic bristle.

To form the photovoltaic portion of the photovoltaic bristles, a number of semiconductor layers may be applied to the inner conducting core using well-known semiconductor processing methods. As illustrated in FIG. 6D, in block 804, a first absorber layer of semiconductor material may be formed over the inner conductive layer. For example, the first absorber layer 105 may include silicon, amorphous silicon, polycrystalline silicon, single crystal silicon, cadmium telluride, cadmium sulfide, gallium arsenide, copper indium selenide, and copper indium gallium selenide. The first absorber layer 105 over the inner conductive layer 107 by electroplating, chemical vapor deposition, atomic layer deposition, etc.

As illustrated in FIG. 6E, in block 842 a second semiconductor material layer may be formed over the first absorber layer, with the first and second absorber layers having material properties to create a p-n junction or n-p junction configured to release electrons upon absorbing a photon. Any deposition method used to add the first absorber layer 105 may also be used to add the second absorber layer 104. In an embodiment, the deposition method for the second absorber layer 104 may be the same deposition method used for adding the first absorber layer 105. In an embodiment, the second absorber layer 104 may include a semiconductor material. For example, the second absorber layer 104 may include silicon, amorphous silicon, polycrystalline silicon, single crystal silicon, cadmium telluride, cadmium sulfide, gallium arsenide, copper indium selenide, and copper indium gallium selenide. In an embodiment, the second absorber layer 104 may be an absorber sublayer or region comprising the same material as the first absorber layer 105 with a different dopant. For example, the first absorber layer 105 may be p-doped amorphous silicon and the second absorber layer 104 may be n-doped amorphous silicon. In an embodiment, the second absorber layer 104 may be an absorber sublayer comprising a different material as the first absorber layer 105. For example, the first absorber layer 105 may be p-doped cadmium telluride and the second absorber layer 104 may be n-doped cadmium sulfide. In optional block 846, additional absorber layers of semiconductor materials may be applied to form multiple p-n and/or n-p junctions (e.g., n-p-n or p-n-p junctions).

With the photon absorber layers formed, an outer conductive layer may be formed in block 848 as illustrated in FIG. 6G. The outer conductive layer may be a transparent conducting oxide or transparent conducting nitride, as are well-known in the photovoltaic technologies. In an embodiment, the only two absorber layers 104, 105 may be applied, and thus the outer conductive layer 103 is deposited (e.g., by chemical deposition or physical deposition) over the last absorber layer 104 as shown in FIG. 6F. In optional block 852, additional outer conductive layers may be applied depending upon the configuration of the photovoltaic bristles. Although the outer conductive layer in FIG. 6G includes two layers, any number of layers may make up the outer conductive layer 103.

Corrugated photovoltaic cells may also be configured using similar processes as illustrated in FIGS. 7A-7C. For example, as illustrated in these figures, the operations of forming an array of cores in the plastic or polymer in block 808 may be accomplished by alternately pressing the material 302 with dies that are oriented at the desired angle of the corrugated surfaces. For example, photovoltaic bristles 106 may be formed on corrugated surfaces in the 1^{st} orientation by pressing the material with dies 702 long one angle as illustrated in FIG. 7B, followed by pressing the opposite surfaces with opposite oriented dies 702 as illustrated in FIG. 7C.

To form the embodiment illustrated in FIG. 4C in which photovoltaic bristles are formed on only alternating sides of the corrugated surface, only a single pressing step as illustrated in FIG. 7B may be a comp push. In some embodiments, in optional block 854 a reflective layer may be applied to the surfaces that do not feature photovoltaic bristles. This may be accomplished using photoelectric graphic methods, such as coding the photovoltaic bristles with a photoresist that is removed from the other surfaces before a reflective layers applied.

As illustrated in FIG. 6H, in optional block 856 but conductive traces may be added to portions of the solar cells to gather and distribute electricity from the photovoltaic bristles, thereby reducing the path length of electrons through the transparent conducting oxide layers. Finally in optional block 858, a transparent coating may be applied over the bristles in order to provide desirable strength and photon absorption c characteristics. For example, a transparent coating 608 may seal each bristle in a transparent material providing stability to each bristle to prevent the bristles from breaking. The transparent coating 608 may be conventional shatterproof material such as ethylene-vinyl acetate (EVA).

In a further embodiment method that uses some of the same processes as in method 800, the material forming the cores 106 may be poured and formed in a mold 612 instead of being pressed, as illustrated in FIGS. 6I through 6K. As illustrated in FIG. 6I, instead of a die 602, the same basic shape may be inverted to form a mold 612 onto which may be poured the material 614 to form the cores and supporting substrate. This material 614 may be a plastic or polymer, but may also be other materials, such as a metal, a ceramic paste, or a liquid glass (e.g., common glass). In this embodiment, the operations of forming the array of cores in block 808 include pouring the base material 614 into the mold 612, sufficiently covering the mold surface to provide a substrate 202 as shown in FIG. 6J. The material may be cured in block 810 in this state before the mold 612 is removed as shown in FIG. 6K. Thereafter, the operations of depositing absorber layers and outer conductive layers may be accomplished as described above with reference to blocks 812-858.

Another embodiment method for forming an array of bristles for a metamaterial device involves a plating up metal cores using a photolithographic methods to create a template on a substrate. The plating up method is illustrated in FIGS. 9A-9J and FIG. 10. In block 1008 a metal layer may be deposited over a substrate. As illustrated in FIG. 9A the metal layer 187 may be deposited directly may be deposited over the substrate 202 by chemical deposition or physical deposition. In block 1010 a photoresist layer over the metal layer. The photoresist layer 189 may be deposited over the metal layer 187 by chemical vapor deposition or physical deposition as shown in FIG. 9A. The photoresist layer 189 may be a positive photoresist or a negative photoresist.

In block 1012 a mask may be applied over the photoresist. As shown in FIG. 9B, the mask 195 may include holes 195a through which ultraviolet light may pass so that only the photoresist beneath the holes is exposed as shown in FIG. 9B. In block 1014 the photoresist layer may be exposed an ultraviolet light through the mask to create exposed photoresist portions 189a as shown in FIG. 9B. When a positive photoresist is used, the exposed photoresist portions 189a match the mask holes 195a. However, if a negative photoresist is used, ultraviolet light may be able to pass through the entire mask except through solid portions of the mask which block the ultraviolet light. Regardless, after the ultraviolet light is applied to the photoresist 189 creating exposed portions 189a, the mask 195 is removed leaving the entire photoresist layer 189.

In block 1016 the method may include developing the photoresist layer to create a template of masked portions. A developer may be used to dissolve only the exposed portions of the photoresist. Assuming the method uses a positive photoresist 189, the exposed photoresist portions 189a are removed creating voids 189b in the photoresist layer that extend to the metal layer 187 as shown in FIG. 9C. These voids 189a along with the remaining photoresist layer 189 form a template over the metal layer 187.

In block 1018 additional metal may be added to the metal layer through the photoresist layer using electroplating, chemical vapor deposition or plasma deposition methods, forming metal cores. As shown in FIG. 9D the metal cores 106 may fill the voids 189b within the photoresist 189 by electroplating metal in the voids 189b. Metal cores may also extend above the photoresist layer. Alternatively, a second metal layer may fill the voids 189b and covers the remaining portions of the photoresist layer 189 (not shown). The metal cores 106 may be the same material as the metal layer 187 such as gold, copper, nickel, molybdenum, iron, aluminum, or silver, or an alloy of the same.

In block 1020 the photoresist layer may be removed using conventional methods. As shown in FIGS. 9D and 9E, the metal cores 106 may only fill the voids 189b created by the exposed photoresist layer through an electroplating process. When the photoresist layer 189 is removed, only the formed metal cores 106 (within voids 189b) remain. Alternatively, if a second metal layer fills the voids 189b and covers the photoresist layer 189, a lift-off process known in the art may remove the photoresist layer 189 and the second metal layer leaving only the metal cores 106. The resulting metal cores 106 from the lift-off process may have height greater than the voids 189b.

In block 1040 a first absorber layer (i.e., sublayer) 105 may be deposited over the metal core 106 for metamaterials 200 illustrated in FIG. 9F. In an embodiment, the first absorber layer 105 may include a semiconductor material. For example, the first absorber layer 105 may include silicon, amorphous silicon, polycrystalline silicon, single crystal silicon, cadmium telluride, cadmium sulfide, gallium arsenide, copper indium selenide, and copper indium gallium selenide. In an embodiment, the first absorber layer 105 may be deposited over the metal core 106 by electroplating, chemical vapor deposition, atomic layer deposition, etc. In an embodiment, the first absorber layer 105 may be deposited over the inner conductive layer 107 by sputtering, electron beam, pulsed laser deposition, etc.

In block 1042 a second absorber layer 104 may be deposited over the first absorber layer 105 for metamaterial 200 as illustrated in FIG. 9G. Any deposition method used with respect to the first absorber layer 105 may also be used with the second absorber layer 104. In an embodiment, the second absorber layer 104 may include silicon, amorphous silicon, polycrystalline silicon, single crystal silicon, cadmium telluride, cadmium sulfide, gallium arsenide, copper indium selenide, and copper indium gallium selenide. In an embodiment, the second absorber layer 104 may be an absorber sublayer or region comprising the same material as the first absorber layer 105 with a different dopant. For example, the first absorber layer 105 may be p-doped amorphous silicon and the second absorber layer 104 may be n-doped amorphous silicon. In an embodiment, the second absorber layer 104 may be an absorber sublayer comprising a different material as the first absorber layer 105. For example, the first absorber layer 105 may be p-doped cadmium telluride and the second absorber layer 104 may be n-doped cadmium sulfide.

In some implementation multiple absorber layers may be applied. So, in optional block 1046 one, two or more additional absorber layers may be applied over the previous layer in a manner similar to the process steps in blocks 1040 and 1042. As shown in FIG. 9H, in block 1048, an outer conductive layer 103 may be deposited over the last absorber layer (e.g., second absorber layer 104), such as by chemical deposition or physical deposition.

As illustrated in FIG. 9I, additional outer conductive layers may be applied in optional block 1052. In an embodiment, the outer conductive layers may comprise a transparent non-conductive layer 103a (e.g., an optical transparent polymer) and a conductive layer 103b (e.g., a transparent conducting oxide). Although the outer conductive layer shown in FIG. 9I includes two layers, any number of layers may make up the outer conductive layer 103. The non-conductive layer 103a illustrated in FIG. 9I may be a conformal layer which may act as a protective coating similar to the transparent coating 608 described below. The conformal non-conductive layer 103a may be added by dip coating, chemical vapor deposition, physical deposition, and atomic layer deposition, and evaporation techniques.

In optional block 1056 current conducting traces may be added to the metamaterials 200 and 300. As explained later with reference to FIGS. 23 and 25, the current conducting traces may be added by creating a template using photolithography and depositing a highly conductive material in a selected position from the template. The current conducting trace may be deposited on the metamaterial by any known deposition method such as chemical vapor deposition, physical deposition, plating, or ink jet material deposition. The ink jet deposition methods may utilize piezoelectric ink jets to add silver or other colloidal conductive material to the desired position without damaging the metamaterial.

Alternatively, the current conductive traces may be added by etching with laser ablation in combination with a deposition method such as ink jet. Tuned wavelength lasers may etch desired layers by controlling the laser's wavelength for different layers within the metamaterial. Once etching is complete, the method may include adding the electrical connections such as the current conducting traces at the desired positions on the metamaterial by chemical vapor deposition, physical deposition, plating or inkjet deposition.

As a further alternative, the metamaterial may be etched using ink jet technology to apply an acid to precise locations followed by applying the conductive material using the same technology, or any other deposition method known in the art.

Regardless of method used, the current conducting traces may allow for efficient transfer of electricity by adding a lower resistant electrical path within the metamaterials.

In optional block 1058 a transparent coating may be deposited over the bristles. As illustrated in FIG. 9J, the transparent coating 608 is different from the outer conductive layer 103 and its sublayers 103a and 103b. The transparent coating 608 may fully fill the voids between each bristle and extending beyond the height of each bristle. As shown, the transparent coating 608 may not be conformal thus leading to deposition methods that use liquid solutions. Thus, the method of depositing transparent coating 608 may include one or more of the following immersion coating, spray gel techniques, extrusion techniques, a spreader bar, photoresist techniques, sol gel techniques, or any other methods known in the art. The transparent coating 608 may seal each bristle providing stability and to prevent them from breaking as well as insulate each bristle from any heat created by the metamaterial device. Observations and experimentations also indicate enhanced peak power generation as the sun translates across the sky for a metamaterial device with a transparent coating 608 having a index of refraction similar to glass (e.g., around 1.5). All these benefits may add enhanced power performance and total power generation of the metamaterial device.

A further method for forming an array of bristles for metamaterial 200 includes forming bristles by etching vias in a substrate through a photolithographic template. The method includes adding an inner conductive layer 107 and a base layer 202b over the original substrate 202a and in the vias. The method then includes turning the metamaterial device over and depositing absorber layers 104, 105, outer conductive layers 103a, 103b and a transparent coating over the inner conductive layer. This via method is illustrated in FIGS. 11A-11L and FIG. 12.

In block 1210 a photoresist layer may be deposited over the substrate. The photoresist layer 189 may be deposited over the substrate 202a by chemical vapor deposition or physical deposition as shown in FIG. 11A. Although FIGS. 11B-11D illustrates a positive photoresist, the photoresist layer 189 may be negative photoresist.

In block 1212 a mask may be deposited over the photoresist layer. The mask 195 may be any suitable mask known in the art. As shown in FIG. 12B, the mask 195 may include mask holes 195a. Alternatively, if using a negative photoresist, the pores 195a may be filters for blocking ultraviolet light.

In block 1214 the method may include exposing an ultraviolet light to the photoresist layer through the mask. The ultraviolet light from the ultraviolet light source 193 passes through the mask holes 195a into the photoresist layer 189 creating exposed portions 189a of the photoresist layer as shown in FIG. 11B. The exposed photoresist portions 189a match the mask holes 195a. However, if a negative photoresist is used, ultraviolet light may be able to pass through the entire mask except through filters where at the locations of mask holes 195a, which block the ultraviolet light. Regardless, after the ultraviolet light is applied to the photoresist layer 189 creating exposed portions 189a, the mask 195 is removed leaving the entire photoresist 189.

In block 1216 the method may include developing the photoresist layer to create a template, such as by using developer to dissolve the exposed portions of the photoresist as shown in FIG. 11C. After dissolving the required portions of the photoresist layer, the remaining photoresist layer 189 portions forms a template over the substrate 202a.

In block 1218 the substrate may be etched through the template creating vias. Etching may include wet etching or dry etching. Regardless of the etching technique, vias 1103 are formed from within the substrate 202a.

In block 1220 the photoresist layer may be removed as shown in FIGS. 11D-11E, leaving only the original substrate 202a with formed vias 1103. Any process known in the art may remove the photoresist layer 189 from the substrate. For example, the photoresist may be removed by stripping or dissolving the remaining portion of the photoresist.

In block 1222 an inner conductive layer may be deposited in the vias. As shown in FIG. 11F, the inner conductive layer 107 may be deposited as a layer that covers the bottoms and the sides of the vias 1103 as well as covering the top of the substrate 202a. Although the method steps do not explicitly show it, the inner conductive layer 107 may include multiple layers similar to the outer conductive layer 103 later described with reference to blocks 1248, 1450, and 1452.

As shown in FIG. 11G, in block 1224 the base layer may be deposited over the inner conductive layer 107. Although the base layer 202b is a separate layer than the original substrate 202a, it may be the same material as the original substrate 202a. Alternatively, the base layer 202b may be a different substance. It should be noted, that although FIG. 11G illustrates the base layer 202b completely fills the vias 1103, the base layer may 202b may only partially fill the vias 1103 and may be deposited similar to the inner conductive layer 107 resulting in an unfilled void and a non-solid core.

In block 1226 the device may be turned over, and the substrate etched in block 1228. FIG. 11H illustrates the metamaterial device turned over (i.e., flipped 180 degrees) as well as the original substrate etched away leaving the inner conductive layer 107 and the base layer 202b. A wet etching process (i.e., using acid) or a dry etching process may remove the original substrate 202a resulting.

In block 1240 the method may be depositing a first absorber layer. The first absorber layer (i.e., sublayer) 105 may be deposited over the inner conductive layer 107 for metamaterial 200 as illustrated in FIG. 11I. In an embodiment, the first absorber layer 105 may include a semiconductor material. For example, the first absorber layer 105 may include silicon, amorphous silicon, polycrystalline silicon, single crystal silicon, cadmium telluride, cadmium sulfide, gallium arsenide, copper indium selenide, and copper indium gallium selenide. In an embodiment, the manufacturing system may add the first absorber layer 105 over the metal core 106 by electroplating, chemical vapor deposition, atomic layer deposition, etc. In an embodiment, the manufacturing system may add the first absorber layer 105 over the inner conductive layer 107 by sputtering, electron beam physical deposition, pulsed laser deposition, etc.

In block 1242 a second absorber layer may be deposited over the first absorber layer 105 for metamaterial 200 as illustrated in FIG. 11I. Any deposition method used to deposit the first absorber layer 105 may be used to deposit the second absorber layer 104. In an embodiment, the deposition method for the second absorber layer 104 may be the same deposition method used for adding the first absorber layer 105. In an embodiment, the second absorber layer 104 may include a semiconductor material. For example, the second absorber layer 104 may include silicon, amorphous silicon, polycrystalline silicon, single crystal silicon, cadmium telluride, cadmium sulfide, gallium arsenide, copper indium selenide, and copper indium gallium selenide. In an embodiment, the second absorber layer 104 may be an absorber sublayer or region comprising the same material as the first absorber layer 105 with a different dopant. For example, the first absorber layer 105 may be p-doped amorphous silicon and the second absorber layer 104 may be n-doped amorphous silicon. In an embodiment, the second absorber layer 104 may be an absorber sublayer comprising a different material as the first absorber layer 105. For example, the first absorber layer 105 may be p-doped cadmium telluride and the second absorber layer 104 may be n-doped cadmium sulfide.

As mentioned above, in some implementations multiple absorber layers may be applied, so in optional block 1246 such additional absorber layers may be over the previous layer in a manner similar to the process steps in blocks 1240 and 1242. As shown in FIG. 11J, in block 1248, an outer conductive layer 103 may be deposited over the last absorber layer (e.g., second absorber layer 104). In optional block 1252, multiple outer conductive layers may be applied as illustrated in FIG. 11K. As discussed above, such outer conductive layers may be applied using chemical deposition or physical deposition.

In optional block 1256 current conducting traces may be deposited on the metamaterials 200. As explained later with reference to FIGS. 23 and 25, the current conducting traces may be added by creating a template using photolithography and depositing a highly conductive material in a selected position from the template. The current conducting traces may be deposited on the metamaterial by any known deposition method such as chemical vapor deposition, physical deposition, plating, or ink jet material deposition. The ink jet deposition may utilize piezoelectric technology and add silver or any other colloidal material to the desired position without damaging the metamaterial. Alternatively, the current conductive traces may be added by etching with laser ablation in combination with a deposition method such as ink jet techniques. Tuned wavelength lasers may etch desired layers by controlling the laser's wavelength for different layers within the metamaterial. Once etching is complete, the method may include adding the electrical connections such as the current conducting traces at the desired positions on the metamaterial by chemical vapor deposition, physical deposition, plating or inkjet deposition. As a further alternative, the metamaterial may be etched by ink jet technology using acid followed by deposition of conductive material using the same technology or any other deposition method known in the art. Regardless of method used, the current conducting traces may allow for efficient transfer of electricity by adding a lower resistant electrical path within the metamaterials.

As illustrated in FIG. 11L, in optional block 1258 a transparent coating may be applied over the bristles. Such a transparent coating 608 may be different from the outer conductive layer 103 and any sublayers 103a and 103b. The transparent coating 608 may fully fill the voids between each bristle and extend beyond the height of each bristle. As shown, the transparent coating 608 may not be conformal thus leading to deposition methods that use liquid solutions. Thus, the method of depositing transparent coating 608 may include using one or more of the following immersion coating, spray gel techniques, extrusion techniques, a spreader bar, photoresist techniques, sol gel techniques, or any other methods known in the art. In an embodiment, the transparent coating 608 may be a shatterproof material such as EVA. The transparent coating 608 may seal each bristle providing stability and to prevent them from breaking as well as insulate each bristle from any heat created by the metamaterial device. Observations and experimentations also indicate enhanced peak power generation as the sun translates across the sky for a metamaterial device with a transparent coating 608 having a index of refraction similar to glass (e.g., around 1.5). All these benefits may add enhanced power performance and total power generation of the metamaterial device.

A further method for forming an array of bristles for a metamaterial 200 includes forming the bristles by etching vias in a substrate through a photolithographic template. Bristles are formed within the vias by depositing an outer conductive layer, absorber layers, an inner conductive layer, an optional base layer. After forming the bristles, the metamaterial may be turned over where the original substrate is left intact serving as a protective coating and an optical enhancement for the metamaterial 200. This via method is illustrated in FIGS. 13A-13L and FIG. 14. As shown in FIG. 13A-13L and the method steps in FIG. 14, an etching technique may be used to create vias, which is particularly useful when using a glass substrate.

In block 1410 a photoresist may be deposited over the substrate. The photoresist layer 189 may be deposited over the substrate 202a by spin on, spray on, or other controlled flow methods know in the art as shown in FIG. 13A. Although FIGS. 13B-13D illustrate a positive photoresist, the photoresist layer 189 may be negative photoresist.

In block 1412 a mask may be positioned over the photoresist layer. The mask 195 may be any suitable mask known in the art. As shown in FIG. 12B, the mask 195 may include mask holes 195a. Alternatively, if using a negative photoresist, the pores 195a may be filters for blocking ultraviolet light.

In block 1414 the method may include exposing an ultraviolet light to the photoresist layer through the mask. The mask 195 may be any suitable mask known in the art. As shown in FIG. 13B, the mask 195 may include mask holes 195a.

In block 1416 the method may include developing the photoresist layer to dissolve the exposed portions of the photoresist layer. Assuming a positive photoresist layer 189, the exposed portions 189a are removed creating voids 189b in the photoresist layer that extend to the substrate 202a as shown in FIG. 13C. After dissolving the required portions of the photoresist layer 189, the remaining photoresist layer 189 forms a template over the substrate 192.

In block 1418 the substrate may be etched through the template creating vias. Etching may include wet etching or dry etching. Regardless of the etching technique employed, vias 1103 are formed from within the substrate 192.

In block 1420 the photoresist layer may be removed leaving the substrate 192 with formed vias 1103 as shown in FIGS. 13D-13E.

Since the outside layers of the photovoltaic bristles are laid down first, conductive traces used to draw current from the photovoltaic cells may be laid down as a first step. Thus, in optional block 1421, conductive traces may be applied to the substrate. Vias for such conductive traces may be formed as part of the operations in blocks 1410-1420. Alternatively, conductive traces may be applied to the substrate using dedicated photolithography steps, laser ablation steps, and deposition steps such as those described above and below. In a particular embodiment, the conductive traces may be applied using spray jet techniques. In block 1422 an outer conductive layer may be deposited in the vias, such as by chemical vapor deposition or physical deposition. If conductive traces are prior to the outer conductive layer, the method may include depositing the outer conductive layer 103 over the conductive traces as a conformal film.

Although not shown in FIGS. 13A-13L, the metamaterial may include an outer conductive layer 103 with multiple sublayers. So, in optional block 1452 another outer conductive layer may be applied over the previous layer, essentially repeating blocks 1450 and 1452. As shown in FIGS. 13G-13H, in block 1440 a first absorber layer may be deposited on the outer conductive layer(s), and in block 1442 a second absorber layer may be deposited over the first absorber layer. The first and second absorber layer 104, 105 may be applied by chemical vapor deposition.

In block 1446 additional absorber layer applied over the previous layer in a manner similar to the process steps in blocks 1440 and 1442. In block 1448, an inner conductive layer 107 may be applied over the last absorber layer (e.g., second absorber layer 105). In an embodiment, the method may include adding only two absorber layers 104, 105 and thus the inner conductive layer 107 is deposited over the last absorber layer 105 by chemical deposition or physical deposition as shown in FIG. 13I. Although the method steps do not explicitly show it, the inner conductive layer 107 may also include multiple layers similar to the outer conductive layer 103.

In block 1424 a base layer may be deposited. As shown in FIG. 13J, the base layer 202 may be different from the substrate 192 associated with block 1410. The base layer 202 may be deposited over the inner conductive layer 107 and serves as the actual bottom substrate of the metamaterial device once the vias are turned over. The base layer 202 may fill the vias 1103 creating bristles with solid cores. Alternatively, as shown in FIG. 13J, the base layer 202 may not fill the vias 1103, creating bristles with non-solid cores. Regardless, the base layer 202 may be deposited over the inner conductive layer 107 by any method known in the art.

In block 1426 the metamaterial may be turned over as shown in FIG. 13K, so that the bristles are turned upright presenting the original substrate 192 covering the outer conductive layer 103 at the top and the base layer 202 at the bottom of the device. In optional block 1460 the substrate may be further processed, such as to form an anti-reflection layer or rough outer surface 192a as shown in FIG. 13L.

In an alternative embodiment method, lasers 2401 may create vias 1103 out of a substrate or index matched material as illustrated in FIGS. 13M through 13O. The lasers 2401 may be controlled in terms of exposure time and energy in order to control the depth and size of the vias. After creating the vias 1103, the method 1400 operations described above with references to blocks 1421, 1448, 1452, 1440, 1442, 1446, 1442, 1422, 1424, 1426, 1458, and 1460 may be followed.

Stamps may create vias out of a substrate such as a transparent polymer. When using a polymer, a UV source may cure the stamped vias creating a more rigid structure followed by adding conductive layers, absorber layers, and a base layer. The stamping via method for forming an array of bristles for a metamaterial device is illustrated in FIGS. 15A-15J and FIG. 16.

In block 1608 an array of vias may be formed out of the processed polymer. As illustrated in FIGS. 15A-15B, a stamping process may be used to create vias 1103 out of a polymer substrate 192. In block 1610 the formed polymer may be cured or otherwise treated to yield desired material properties. For example, such curing/treating may include heating and/or exposure to an ultraviolet light source 193.

Similar to method 1400, the method 1600 includes laying down the outside layers of the photovoltaic bristles are laid down first, so conductive traces used to draw current from the photovoltaic cells may be laid down prior to the outer conductive layer 103. Thus, in optional block 1612, conductive traces may be applied to the substrate. Vias for such conductive traces may be formed as part of the operations in blocks 1608-1610. Alternatively, conductive traces may be applied to the substrate using dedicated photolithography steps, laser ablation steps, and deposition steps such as those described above and below. In particular embodiment, the method may include applying conductive traces using a spray jet techniques. In block 1622 an outer conductive layer may be deposited in the vias. If conductive traces are added prior to the outer conductive layer 103, the method may include depositing the outer conductive layer 103 over the conductive traces as a conformal film. As illustrated in FIG. 15D, the outer conductive layer 103 may be deposited over the polymer 192 and in the vias 1103.

Although it is not shown in FIGS. 15A-15J, multiple outer conductive layers 103 or sublayers may be applied. So, in optional block 1652 additional outer conductive layers may be applied over the previous layer.

As shown in FIGS. 15E-15F, in block 1640 a first absorber layer may be applied over the outer conductive layer(s), and in block 1642 a second absorber layer may be deposited over the first absorber layer. The method may deposit the first and second absorber layer 104, 105 by chemical vapor deposition. In optional block 1646 additional absorber layers may be deposited over the other absorber layers in a manner similar to the process steps in blocks 1640 and 1642.

As shown in FIG. 15G, in block 1648, an inner conductive layer 107 may be applied over the last absorber layer (e.g., second absorber layer 105), such as by chemical vapor deposition or physical deposition. The inner conductive layer 107 may also include multiple layers similar to the outer conductive layer 103 earlier described with reference to blocks 1622, 1650, and 1652.

As shown in FIG. 15H, in optional block 1624 a base layer may be applied. The base layer 202 may be different from the polymer 192 applied in block 1608 because the base layer 202 is deposited over the inner conductive layer 107 and serves as the actual bottom substrate of the metamaterial device once turned over. Although the polymer 192 may be of the same material as the base layer 202, the polymer 192 may serve as an outer transparent coating to the metamaterial device once the metamaterial is complete. The base layer 202 may fill the vias 1103 creating bristles with solid cores. Alternatively, as shown in FIG. 15J, the base layer 202 may not fill the vias 1103, creating bristles with non-solid cores. Regardless, the base layer 202 may be deposited over the inner conductive layer 107 by any method known in the art.

As shown in FIG. 15I, in block 1626 the metamaterial may be turned over for further processing. In optional block 1660 the substrate 192 may be processed to give it desired physical properties, such as hardening or polishing. The processing may include forming an antireflection layer or rough outer surface 192a as shown in FIG. 15J.

In a further embodiment method that uses some of the same processes as in method 1600, material 1112 in which vias 1103 are poured into a mold 1110 instead of being pressed, as illustrated in FIGS. 15K through 15M. As illustrated in FIG. 15K, instead of a die, the same basic shape may be inverted to form a mold 1110 onto which may be poured the material 1112 to form the vias 1103 and supporting substrate. This material 1113 may be a transparent plastic, polymer or glass that will ultimately have the desired optical properties in the finished product. In this embodiment, the operations of forming the array of vias 1103 in block 1608 include pouring the base material 1112 into the mold 1110, sufficiently covering the mold surface to provide a substrate 1112 as shown in FIG. 15L. The material may be cured in block 1610 in this state before the mold 1110 is removed as shown in FIG. 15M. Thereafter, the operations of depositing outer conductive layers, absorber layers and inner conductors may be accomplished as described above with reference to blocks 1612-1626.

As a further alternative embodiment, vias may be formed by adding an index-matched nano-imprinted layer over a substrate. The nano-imprinted layer comprises the vias for methods 1200, 1400, 1600 and may use suitable nano-imprinting techniques known in the art. For example, methods 1200, 1400, and 1600 may include depositing a nano-imprinted layer material with a index of refraction of 1.5 over a glass or polymer substrate.

FIGS. 17-21 illustrate multiple embodiment metamaterials 1700, 1900, 2100 with current conducting traces 1701, 1702, 1703, 1901, 2101 applied to reduce electrical resistance within the metamaterials. The current conducting traces 1701, 1702, 1703, 1901, 2101 provide an electrical path for flowing electrons from the outer conductive layer 103 in metamaterials 200, 300, 400 to collector contacts on the edges of the cells. Electrons may travel from the outer conductive layer 103 via the current conducting traces 1701, 1702, 1703, 1901, 2101 to the outer edge of the metamaterials 1700, 1900, 2100 where they connect to bus bars or high capacity conductors. By reducing the electrical resistance within metamaterials 1700, 1900, 2100 less electrical energy will be converted to heat and more electrical power may be produced. The embodiment metamaterials 1700, 1900, 2100 described below may include current conducting traces 1701, 1702, 1703, 1901, 2101 in any combination or sub-combination.

FIG. 17 illustrates a cross-sectional side view of a metamaterial 1700, which is similar to metamaterial 200 but with current conducting traces 1701, 1702, and 1703. In an embodiment, metamaterial 1700 may include current conducting trace 1701 on top of the outer conductive layer 103 of a row of shorter photovoltaic bristles 1704. Although FIG. 17 shows only one row of shorter photovoltaic bristles 1704 with a current conducting trace 1701 on the shorter photovoltaic bristles 1704, in an embodiment there may be multiple rows of shorter photovoltaic bristles 1704 with current conducting traces 1701 on top.

In an embodiment, metamaterial 1700 may include current conducting traces 1702, 1703 in different locations than current conducting trace 1701. As with the current conducting trace 1701, metamaterial 1700 may include current conducting trace 1702 on top of the outer conductive layer 103 but positioned at the end of the array of photovoltaic bristles 201. Metamaterial 1700 may include current conducting trace 1703 on top of the substrate 202 or in contact with the inner conductive layer 107 to allow efficient electron flow. Electrons may flow from the absorber sublayer 105 to the outer conductive layer 103 through the current conducting traces 1701, 1702 to the electrical destination (e.g., electrical storage, electrical converter, or motor) and the circuit is completed by connecting current conducting trace 1303 to the inner conductive layer 107 or metal substrate 202. Alternatively, electrons may flow from the absorber layer 105 through the inner conductive layer 107 to the current conducting trace 1303 and then to an electrical destination (e.g., electrical storage, power converter, etc).

FIG. 18 illustrates the top view of FIG. 17 of metamaterial 1700 with current conducting traces 1701, 1702, 1703. In an embodiment, metamaterial 1700 may include current conducting trace 1701 on top of an array of shortened photovoltaic bristles 1704 extending along the width of the array. Similarly, current conducting traces 1702 and 1703 may extend along in the same direction of the array. Connecting current conducting traces 1701 and 1702 to current conducting traces 1703 may create a complete circuit in the metamaterial 1700, thereby allowing current to flow through the array of bristles when struck by photons sufficient to generate electron movement.

FIG. 19 illustrates a cross-sectional side view of a metamaterial 1900, which is similar to metamaterial 200, but with current conducting traces 1901, 1702, 1703. In an embodiment, metamaterial 1900 may include current conducting trace 1901 on the outer conductive layer 103 between the photovoltaic bristles 201. As with FIG. 17, metamaterial 1900 may include current conducting traces 1702 on the outer conductive layer 103 and current conducting traces 1703 on the substrate 202 and/or in contact with the inner conductive layer 107. In contrast with FIG. 17, metamaterial 1900 may not include a row of shorter photovoltaic bristles 1704 because current conducting traces 1901 are between the photovoltaic bristles 201 on top of the outer conductive layer 103. However, in an embodiment, metamaterial 1900 may include a row of shorter photovoltaic bristles 1704 with a current conducting trace 1701 on the shorter photovoltaic bristles 1704 in addition to the current conducting traces 1901 positioned between photovoltaic bristles 201.

FIG. 20 illustrates the top view of FIG. 19 of an array of photovoltaic bristles 201 on a flat substrate 202 with current conducting traces 1901 positioned between photovoltaic bristles 201. Similar to the current conducting traces 1701, 1702, 1703 in FIG. 18, the current conducting traces 1901, 1702, and 1703 extend the entire width of the array. In an embodiment, the current conducting traces 1901, 1702, 1703 may extend in any direction. For example, the current conducting traces 1901, 1702, and 1703 may extend diagonally, along the length, and/or along the width of the metamaterial 1900.

FIG. 21 illustrates a cross-sectional side view of a portion of metamaterial 2100 similar to metamaterial 300, but with current conducting traces 2101, 1702, 1703. Metamaterial 2100 includes current conducting trace 2101, which may be located between photovoltaic bristles 301 as well as at the peak and trough of the slanted substrate surfaces 308a, 309a, 308b, 309b. In an embodiment, metamaterial 2100 includes current conducting traces 1702, 1703 at the ends of the metamaterial 2100 similar to FIGS. 17 and 19. Current conducting trace 1702 may be on the outer conductive layer 103 at the ends of the array of photovoltaic bristles 301. Current conducting trace 1703 may be on top of the substrate 302 and/or in contact with the inner conductive layer 107. In an embodiment, metamaterial 2100 may include current conducting traces 2101 on top of the outer conductive layer 103 and between photovoltaic bristles 301 located on the peak and/or the trough of the slanted substrate surfaces 308a, 309a, 308b, 309b. Although it is not shown in FIG. 21, the metamaterial 2100 may have current conducting traces 2101 positioned on the outer conductive layer 103 on top of shorter photovoltaic bristles 1704 as shown in FIG. 17. In an embodiment, metamaterial 2100 may be similar to metamaterial 400 as it may be without photovoltaic bristles 401 on slanted substrate surfaces 409a, 409b. For example, the metamaterial may include current conducting traces 2101 between photovoltaic bristles 401 only on alternating slanted substrate surfaces 408a, 408b, etc.

Photolithographic techniques may be used to deposit the current conducting traces 1701, 1702, 1703, 1901, and 2101 of FIGS. 17-21 on metamaterials 200, 300, and 400. These current conducting traces may be added to the metamaterials regardless of whether the metamaterials are created through stamping, vias, or any other technique. Although photolithographic techniques are used for adding each current conducting trace 1701, 1702, 1703, 1901, and 2101 to the metamaterial device, when adding current conducting trace 1703 to a metamaterial a different method may be used. Thus, FIGS. 22A-22F illustrate and FIG. 23 describes by the method steps for forming current conducting traces 1701, 1702, 1901, and 2101, while FIGS. 24A-24J illustrate and FIG. 25 describes the methods steps for forming current conducting trace 1703. Each method is discussed in turn.

Current conducting traces 1701, 1702, 1901, and 2101 may be formed on metamaterials 200, 300, and/or 400. In block 2302 a photoresist layer may be deposited over the metamaterial. As shown in FIGS. 22A and 22B, a photoresist layer 189 may be deposited over the metamaterial. In block 2304 a mask may be positioned over the photoresist layer. In block 2306 the photoresist layer may be exposed to UV light through the mask. As illustrated in FIG. 22C, exposing only a portion of the photoresist 189 to UV radiation creates an exposed portion 189a within the photoresist layer 189. In block 2308 the photoresist layer 189 may be “developed” by exposing it to chemicals that remove the exposed portions 189a leaving a protective template, and the assembly may be etched to create pores 189b shown in FIG. 22D. In optional block 2310 the substrate may be etched through the template. This step may be required when the metamaterial is formed with vias in methods 1400 or 1500. When creating photovoltaic bristles using vias, the original substrate 192 (shown in FIGS. 13K and 15I) may form a protective coating over the bristles. Thus, the method may include an etching step to expose the outer conductive layer 103 through the substrate 192 before depositing current conducting traces 1701, 1702, 1901, and 2101 on the outer conductive layer 103 eventually followed by filling the etched void in the substrate 192 with a transparent coating. In block 2322 a current conducting trace may be deposited on the metamaterial. Current conducting traces 1701, 1702, 1901, and 2101 may be deposited on the outer conductive layer 103 through photoresist template as shown in FIG. 22E. In block 2312 the photoresist layer may be removed. As shown in FIG. 22F, when the photoresist 189 is removed, only the bristles and the current conducting trace remains. After removing the photoresist, a transparent coasting may be applied to the solar cell covering the bristles and the deposited current conducting trace.

As an alternative to photolithographic techniques, a method for depositing the current conductive traces may include an ink jet device 2201 illustrated in FIGS. 22G and 22H to reduce manufacturing cost. The ink jet 2201 may deposit a conductive trace 1901 in desired locations (e.g., between bristles) by using colloidal material such as silver without the use of the multiple steps associated with photolithographic techniques. Thus, this alternative may include only one-step of depositing a conductive trace on the metamaterial in block 2322.

Current conducting trace 1703 may be formed by a different method as illustrated in FIGS. 24A-24J and FIG. 25. In block 2502 a first photoresist layer may be deposited over the metamaterial. As shown in FIG. 24A, a first photoresist layer 189 may be deposited over and between the bristles of the metamaterial. In block 2504 a first mask may be positioned over the first photoresist layer. As shown in FIG. 24B, the first mask 195 may block UV radiation to the photoresist 189 except through mask portion 195a. This controls the UV radiation to the desired portion of the photoresist layer 189. In block 2506 the method may include exposing a UV source to the first photoresist layer through the first mask to create an etching template. As illustrated in FIG. 24B, exposing only a portion of the photoresist layer 189 to UV radiation creates an exposed portion 189a within the photoresist layer 189. After creating the exposed portion 189a within the photoresist, the mask may be subsequently removed from the metamaterial. In block 2508 the first photoresist layer may be developed. For a positive photoresist layer this includes removing the exposed portion 189a leaving a template created by the remaining photoresist layer 189 with pores 189b as shown in FIG. 24C. In block 2510 the method may include etching the metamaterial through the etching template. As illustrated in FIG. 24D, the photoresist template 189 controls the etching process by removing only a portion of the outer conductive layer 103, the first absorber layer 105, and the second absorber layer 104. In block 2512 the first photoresist layer may be removed. As shown in FIG. 24E, after removing the first photoresist layer 189, the metamaterial may include a void in the outer conductive layer and the absorber layers. In block 2514 a second photoresist layer may be deposited over the metamaterial. As shown in FIG. 24F the second photoresist layer 190 covers the bristles and the void in the metamaterial created by the etching step. In block 2516 a second mask may be positioned over the second photoresist layer. As shown in FIG. 24G, a second mask 196 may block the UV radiation to the second photoresist layer 190 except through the second mask portion 190a. This controls the UV radiation to the desired portion of the second photoresist layer 190. In block 2518 the method may include exposing a UV source to the second photoresist layer through the second mask. As illustrated in FIG. 24G, exposing only a portion of the second photoresist layer 190 to UV radiation creates a second exposed portion 190a within the second photoresist layer 190. After creating the second exposed portion 190a within the second photoresist layer, the second mask may be subsequently removed from the metamaterial. In block 2520 the second photoresist layer may be developed. For a positive photoresist this includes removing the second exposed portion 190a leaving a template created by the remaining second photoresist layer 190 with pores 190b as shown in FIG. 24H. In block 2522 a current conducting trace may be deposited on the metamaterial. Current conducting trace 1703 may be deposited on the inner conductive layer 107 through the second photoresist pore 190b as shown in FIG. 24I. In block 2524 the second photoresist layer may be removed. As shown in FIG. 24J, when the second photoresist layer 190 is removed, only the bristles and the current conducting trace 1703 remains. After removing the photoresist, a transparent coasting may be applied to the metamaterial covering the bristles and the deposited current conducting trace.

In another embodiment method that uses some of the same processes as in method 2500, the steps for etching may include laser ablation using a wavelength-tuned laser to etch only the desired layers, as illustrated in FIGS. 24K through 24M. This may reduce the number of steps associated with the photolithographic techniques of method 2500 thereby reducing manufacturing cost. As illustrated, a wavelength-tuned laser 2401 may be used to etch desired exposing a desired portion of the metamaterial for a conductive trace. Since this technique provides a controlled etching alternative, it allows for any of the methods above to deposit current conducting traces at any point within the method steps.

As an alternative embodiment to the conductive traces described above, high conductive regions may be applied to the various metamaterials though directional deposition such as solid angle physical vapor deposition or ion source deposition. The method may include preferentially coating highly conductive regions with metal while leaving other regions with minimal coating to refrain from blocking entering photons. For example, the method may include coating the area between the vias or bristles ten times as thick as the coating along the sidewalls of the vias or bristles allowing photons to pass through the sidewalls while simultaneously creating a highly conductive region to act as a conductive trace. As another example, the method may include using a thicker conductive coating only on the side of bristles or vias that will receive less exposure to photons during operation of the completed metamaterial. To accomplish the single region deposition, the method may include angling the substrate during the deposition process so that only the desired side receives the highly conductive coating. Regardless of the exact process, the conductive regions may be applied to any of the methods listed above.

Metamaterials 200, 300, 400, 1700, 1900, and 2100 formed by any of the processes above may be assembled into a solar panel. As briefly described above, the corrugated shape may be incorporated into an assembled solar panel as illustrated in FIGS. 26-32. The panel assembly may include a corrugated base with panel surfaces angled at approximately 30 to 60 degrees for increasing off-axis photon absorption in metamaterials 200 with flat substrates as well as an increasing the planar bristle density without increasing shadowing, resulting in similar gains in total efficiency and power generation from metamaterials 300, 400 with corrugated substrates. However, the total efficiencies gains are compounded when the panel assembly and metamaterials include a corrugated shape (e.g., metamaterial 300 in a corrugated solar panel assembly) because the assembled panel benefits from an increase in planar bristle density and off-axis photon absorption.

FIGS. 26-32 illustrate an embodiment solar panel 3100 with a corrugated base 2610. Solar panels with a corrugated base 2610 may be formed by assembling metamaterials 200, 300, 400, 1700, 1900, and/or 2100 together. FIG. 26 illustrates a perspective view of a section of a solar panel 2600. Solar panel section 2600 may include one or more panel surfaces 2602, 2604 in an alternating fashion on a corrugated base 2610. In an embodiment, each panel surface 2602, 2604 may include metamaterials 200, 300, 400, 1700, 1900, and/or 2100 with photovoltaic bristles 201, 301, 401. In an embodiment, panel surfaces 2602, 2604 may include the same metamaterial. For example, each panel surface 2602, 2604 may include metamaterials 200 with a flat substrate 202. In an embodiment, panel surfaces 2602, 2604 may include different metamaterials. For example, panel surfaces 2602 may include metamaterials 200 with flat substrates 202 while panel surfaces 2604 may include metamaterials 300 with corrugated substrates 302. In an embodiment, a first panel surface 2602 may include metamaterials 200, 300, 400, 1700, 1900, and/or 2100, while a second panel surface 2604 is without metamaterial 200, 300, 400, 1700, 1900, and/or 2100. For example, solar panel section 2600 may include a first panel surface 2602 with metamaterials 300 alternating along a corrugated base 2610 with a second panel surface 2604 without metamaterials. In an embodiment, a second panel surface 2604 without metamaterials 200, 300, and/or 400 may include a reflective film (i.e., a mirror). For example, the first and second panel surfaces 2602, 2604 may alternate along the corrugated base 2610 with a first panel surface 2602 with metamaterials 400 and a second panel surface 2604 with only a reflective film. Regardless, each panel surface 2602, 2604 rests on the front of a corrugated base 2610.

In an embodiment, fasteners 2612 may be used to fasten the panel surfaces 2602, 2604 to the corrugated base 2610 with connectors 2608. The same fastener 2612 may also fasten the rails 2902 (shown in FIG. 29) to the corrugated base 2610 and the connectors 2608. In an embodiment, solar panel section 2600 may include a buss bar 2606 with connectors 2608 to connect the buss bar 2606 to each metamaterial 200, 300, 400, 1700, 1900, and/or 2100 of the panel surfaces 2602, 2604. In an embodiment, the buss bar 2606 may connect to the corrugated base 2610 in a slot 2614 of the corrugated based 2610. The slot 2614 may provide stability for the buss bar 2606 as well as allow solar panel section 2600 to rest on a flat back of the corrugated base 2610.

FIG. 27 illustrates a top view of solar panel section 2600. As illustrated with FIG. 26, the solar panel section 2600 may include panel surfaces 2602, 2604, a corrugated base 2610, a buss bar 2606, fasteners 2612, and connectors 2608.

FIG. 28 illustrates a side view of solar panel section 2600. As illustrated, the connectors 2608 may use a single fastener 2612 for each pair of panel surfaces 2602, 2604. The fastener 2612 may be any means of fastening the connectors 2608 to the corrugated base 2610 and the panel surfaces 2602, 2604. For example, the fasteners 2612 may utilize a bolt, a joint, a rivet, screws, a pin, clips, latch, etc. In an embodiment, the fastener 2612 may be metal or metalized to create an electrical pathway from the metamaterials 200, 300, 400, 1700, 1900, and/or 2100 of panel surfaces 2602, 2604 to the connectors 2608. As referenced in FIG. 26 the corrugated base 2610 may have a slot 2614 for the buss bar 2606. The slot 2614 may allow the buss bar 2606 to connect to the backside of the corrugated base 2610 and form a flat surface (i.e. flat back) of the corrugated base 2610. The flat surface of the backside of the corrugated base 2610 may allow for a more stable assembly for the completed solar panel 2600.

FIG. 29 illustrates an exploded view of a solar panel section 2600. As illustrated, rail 2902 may be secured to the corrugated base 2610 by a securing mechanism 2901. The rail 2902 may be secured to the corrugated base 2610 by any means possible. For example, the rail 2902 may be secured to the backside of the corrugated base 2610 by a rivet, crimping, a bolt, adhesive or any other securing means. In another example, the rail 2902 may be secured to the corrugated base 2610 similar to a fastener 2612 used to fasten the panel surfaces 2602, 2604 to the corrugated base 2610. In an embodiment, the rail 2902 also may be fastened by the fastener 2612 to panel surfaces 2602, 2604 on the backside of the corrugated base 2610 opposite the connectors 2608. In an embodiment, the rail 2902 may be fastened to the panel surfaces 2602, 2604 by any means possible including the fastening means as described with reference to FIG. 28. In an embodiment, the buss bar 2606 may be secured to the corrugated base 2610 by a securing mechanism 2901. In an embodiment, the buss bar 2606 may be attached to the rail 2902 with an attachment mechanism 2904. The attachment mechanism 2904 may be any means of attachment. The attachment mechanism may be the same as the securing mechanisms 2901, or the fasteners 2612 as described above.

In an embodiment, the rails 2902 and the buss bars 2606 may be electrically connected to the metamaterials 200, 300, 400, 1700, 1900, and/or 2100 of panel surfaces 2602, 2604. In an embodiment, the rails 2902 may be electrically connected to connectors 2608. The connectors 2608 may be electrically connected to the panel surfaces 2602, 2604 including metamaterials 200, 300, 400, 1700, 1900, and/or 2100. The metamaterials 200, 300, 400, 1700, 1900, and/or 2100 may create electron movement when the photovoltaic bristles 201, 301, 401 are struck by photons. In an embodiment, the outer conductive layer 103 of metamaterials 200, 300, 400 illustrated in FIGS. 2B, 3B, and 4B may be electrically connected to connectors 2608. In an embodiment the current conducting traces 1701, 1702, 1703, 1901, and/or 2101 of metamaterials 1700, 1900, 2100 as illustrated in FIGS. 17, 19, and 21 may be electrically connected the connectors 2608 to help reduce the electrical resistance in the metamaterial 1700, 1900, 2100. Regardless, electron movement may create electricity to flow from the metamaterials 200, 300, 400, 1700, 1900, and/or 2100 within the panel surfaces 2602, 2604 to the connectors 2608 to the rails 2902 and buss bars 2606 connected to the rails 2902. From the rails 2902 and buss bars 2606, the electricity may flow to other rails 2902 and buss bars 2606 in neighboring panel sections 2600 and eventually to an electrical destination (e.g. electrical storage) connected to the completed solar panel 3100.

FIG. 30 illustrates a back view of a solar panel section 2600. As discussed earlier, the buss bar 2606 of the solar panel section 2600 may have a securing mechanism 2901 to help stabilize the buss bar 2606 on the backside of the corrugated section 2600. In an embodiment, each buss bar 2606 may have one or more securing mechanism 2901 to secure the buss bar 2606 to the back of the corrugated base 2610. Alternatively, each buss bar 2606 may not have a securing mechanism 2901 with the corrugated base 2610 and may be secured and connected only with the rails 2902. Although FIGS. 26-30 depict a solar panel section 2600 with two rails 2902 and two buss bars 2606, a solar panel section 2600 may have any number of rails 2902 and buss bars 2606. Some examples of solar panel sections 2600 with a different number of rails include solar panel sections with one rail, two rails, three rails, four rails, five rails, etc. Some other examples of solar panel sections with a different number of buss bars include panel sections with one buss bar, two buss bars, three buss bars, four buss bars, five buss bars, etc.

FIG. 31 illustrates a perspective view of a solar panel 3100 with multiple solar panel sections 2600. In an embodiment, each solar panel section 2600 may include metamaterials 200, 300, 400. In another embodiment, the metamaterials may include current conducting traces 1701, 1702, 1703, 1901, 2101 as illustrated in metamaterials 1700, 1900, or 2100 of FIGS. 17, 19, and 21. In an embodiment, each solar panel section 2600 may be adjacent and combine with one or more other solar panel sections 2600. In an embodiment, the solar panel 3100 may include a frame 3102 that surrounds the outer perimeter of the combined solar panel sections 2600 within the solar panel 3100.

FIG. 32 illustrates an exploded view of a solar panel 3100. In an embodiment, the solar panel 3100 may include a frame 3102, a top cover 3202, and a back cover 3208. In an embodiment, the frame 3102 is connected with corner brackets 3206 and fasteners 3204 to the corners of solar panel sections 2600 positioned in the corners of solar panel 3100. In an embodiment, the frame 3102 for solar panel 3100 may include two short pieces 3214a, 3214b and two long pieces 3216a, 3216b to attach along the four sides of the assembled solar panel sections 2600. In an embodiment, the solar panel 3100 may have four or more corner brackets 3206 (e.g., eight as shown) to connect the pieces of the frame 3102 to the assembled solar panel sections 2600.

In an embodiment, the top cover 3202 of the solar panel 3100 may be transparent or semitransparent. The top cover 3202 may protect the solar panel section 3100 and their electrical and photovoltaic components. For example, the top cover 3202 may protect the solar panel section 2600 and their electrical and photovoltaic components from oxygen corrosion, wind, water, and dirt or anything else that may reduce the efficiency or life of the metamaterials 200, 300, 400, 1700, 1900, and/or 2100 in solar panel 3100.

In an embodiment, the back cover 3208 of solar panel 3100 may include rounded slots 3212 so that fasteners 3210 may connect the back cover 3208 to the assembled (i.e., combined) solar panel sections 2600. The fasteners 3210 may be any type that may connect the back cover 3208 to the assembled solar panel sections 2600. For example, the fasteners 3210 may fasten similar to the fasteners 2612 as described with reference to FIG. 28 (e.g., by bolts, screws, etc.).

In an embodiment, the back cover 3208 and the top cover 3202 may be sealed within the solar panel 3100 by the frame 3102. In an embodiment, only the back cover 3208 or the top cover 3202 may be sealed within the solar panel 3100 by the frame 3102. The back cover 3208 and the top cover 3202 may provide structural support to the solar panel 3100 and its subparts. In addition, the back cover 3208 and the top cover 3202 may protect the subparts of the solar panel 3100 from any contamination that may reduce the efficiency and life of the metamaterials 200, 300, 400, 1700, 1900, and/or 2100 in solar panel 3100 such as wind, water, dirt or oxygen, etc.

In another embodiment, the volumetric efficiency gains realized from the solar panel with the corrugated sections may be achieved by mounting completed solar panels in corrugated patterns with respect to each other. Thus, completed solar panels may be mounted in an array of solar panels where the surfaces of each solar panel form an angle of approximately 30 to 60 degrees with a common plane such as a base connecting the solar panels that is perpendicular to the sun. As an alternative embodiment, reflectors may replace some completed solar panels in the corrugated pattern to help maximize efficiency gain of each completed solar panel.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. A solar panel, comprising:
at least one panel surface, each panel surface is angled from a base and comprises a plurality of metamaterials, and each metamaterial comprising:
a substrate having a top surface; and
an array of photovoltaic bristles extending from the top surface of the substrate, each photovoltaic bristle comprising:
a core;
an inner conductive layer
an absorber layer surrounding the inner conductive layer; and
an outer conductive layer surrounding the absorber layer.

2. The solar panel of claim 1, wherein the panel surface is angled about 30 to about 60 degrees from the base of the solar panel.

3. The solar panel of claim 2, wherein the base of the solar panel is corrugated with a first panel surface and a second panel surface.

4. The solar panel of claim 3, wherein the first panel surface comprises a plurality of metamaterials and the second panel surface is without metamaterials.

5. The solar panel of claim 4, wherein the second panel surface comprises a reflective layer selected for high reflective photon capabilities.

6. The solar panel of claim 5, wherein the corrugated base comprises a third panel surface comprising a plurality of metamaterials and the second panel surface is between the first and third panel surfaces.

7. A method for manufacturing a metamaterial, comprising:
depositing a metal layer over a substrate;
creating a template using photolithographic techniques;
plating the metal layer through the template to form an array of metal cores;
removing the template;
depositing an absorber layer over the array of metal cores; and
depositing an outer conductive layer over the absorber layer.

8. The method of claim 7 further comprising depositing a second outer conductive layer.

9. The method of claim 7, further comprising adding one of current conducting traces or conductive regions to the metamaterial.

10. The method of claim 7, further comprising adding a transparent coating over the metamaterial.

11. The method of claim 7, wherein the array of cores are about 0.01 microns to about 100 microns in height.

12. A method for manufacturing a metamaterial, comprising:
forming an array of vias in a transparent material;
depositing an outer conductive layer over the array of vias;
depositing an absorber layer over the outer conductive layer; and
depositing an inner conductive layer over the absorber layer.

13. The method of claim 12, further comprising adding one of current conducting traces or conductive regions to the metamaterial.

14. The method of claim 12, further comprising depositing a base layer over the inner conductive layer.
